(19) United States
(12) Patent Application Publication
(10) Pub. No.: US 2022/0390512 A1
(43) Pub. Date: Dec. 8, 2022

(54) SYSTEMS AND DEVICES FOR INTELLIGENT INTEGRATED TESTING

(71) Applicant: TestEye Technologies Inc., Collegeville, PA (US)

(72) Inventor: Edward Wilson, Collegeville, PA (US)

(21) Appl. No.: 17/832,005

(22) Filed: Jun. 3, 2022

Related U.S. Application Data
(60) Provisional application No. 63/196,407, filed on Jun. 3, 2021.

(51) Int. Cl. G01R 31/317; G06F 11/36

(52) U.S. Cl. CPC G01R 31/31701; G06F 11/3636; G01R 31/31722

(57) ABSTRACT

Described herein are systems and devices for testing electrical circuits. An example integrated test system includes a unit under test (UUT), a test development system operably coupled to the UUT, the test development system being configured to perform in-circuit testing (ICT) on the UUT and a functional platform brain operably coupled to the test development system and the UUT, the functional platform brain being configured to perform functional testing (FCT) on the UUT using a test sequence protocol, wherein the test sequence protocol is configured to facilitate communication between the test development system and the functional platform brain.

### CROSS-REFERENCE TO RELATED APPLICATIONS

This application claims the benefit of U.S. provisional patent application No. 63/196,407, filed on Jun. 3, 2021, and titled “SYSTEMS AND DEVICES FOR INTELLIGENT INTEGRATED TESTING,” the disclosure of which is expressly incorporated herein by reference in its entirety.

### BACKGROUND

Integrated test strategies are essential testing techniques for electronic devices. Integrating two or more integrated test strategies simultaneously can sometimes require that one or more test strategies exclude a test in order to enable the integration of multiple test strategies.

For example, an original equipment manufacturer (OEM) may need to choose between two tests. One of the tests is a high frequency signal from a voltage-controlled oscillator outside of the measuring capability of the in-circuit test system, but this signal has a direct current (DC) component. Configuring the conventional test system to measure both the high frequency signal and DC component results in less accurate and/or slower tests.

Therefore, what is needed are systems, appliances, and methods for integrating test systems, including systems, devices and methods for integrating different types of tests across different test systems.

### SUMMARY

An example system for performing intelligent integrated testing is described herein. The system includes an integrated test system, including: a unit under test (UUT); a test development system operably coupled to the UUT, the test development system being configured to perform in-circuit testing (ICT) on the UUT; and a functional platform brain operably coupled to the test development system and the UUT, the functional platform brain being configured to perform functional testing (FCT) on the UUT using a test sequence protocol, where the test sequence protocol is configured to facilitate communication between the test development system and the functional platform brain.

In some implementations, the test sequence protocol includes a handshake protocol. Optionally, the test sequence protocol defines a format for exchanging messages between the test development system and the functional platform brain. Optionally, the format for exchanging messages is at least one of a hexadecimal, decimal, or multi-bit format.

Alternatively or additionally, the test sequence protocol is further configured to facilitate communication between the functional platform brain and an application running on the test development system.

In some implementations, the test development system is operably coupled to a plurality of test points of the UUT. Optionally, the functional platform brain is operably coupled to a test access port and a plurality of test points of the UUT.

In some implementations, the system includes a data acquisition unit (DAQ), where the DAQ operably couples a multibit interface of the test development system to a serial port of the functional platform brain.

In some implementations, the system includes a digital input/output scan (DIOS) module carrier, where the DIOS module carrier operably couples the functional platform brain to a plurality of test points of the UUT.

In some implementations, the functional platform brain is configured to perform a boundary scan test using the DIOS module carrier to access the UUT.

In some implementations, the functional platform brain is configured to perform a radiofrequency (RF) test on the UUT.

In some implementations, the ICT includes one or more of a capacitor discharge test, a contact test, a short test, an analog component test, a digital component test, an open pin test, a capacitor orientation test, a UUT power up test, a boundary scan test, or a memory test.

In some implementations, the FCT includes applying a stimulus to the UUT, measuring a response from the UUT, and analyzing the response from the UUT.

In some implementations, the functional platform brain is further configured to perform in-system programming, on-board programming, an engineering verification test, or a production verification test. Alternatively or additionally, the functional platform brain is configured to, using a machine learning algorithm, troubleshoot FCT diagnostic issues.

An example intelligent test fixture is also described herein. The intelligent test fixture includes a functional platform brain that is configured to perform functional testing (FCT) on a unit under test (UUT), where the functional platform brain is configured to use a test sequence protocol, the test sequence protocol being configured to facilitate communication between a test development system and the functional platform brain.

In some implementations, the test sequence protocol includes a handshake protocol. Optionally, the test sequence protocol defines a format for exchanging messages between the test development system and the functional platform brain. Optionally, the format for exchanging messages is at least one of a hexadecimal, decimal, or multi-bit format.

Alternatively or additionally, the test sequence protocol is further configured to facilitate communication between the functional platform brain and an application running on the test development system.

In some implementations, the test fixture includes a digital input/output scan (DIOS) module carrier, where the DIOS module carrier operably couples the functional platform brain to a plurality of test points of the UUT.

In some implementations, the functional platform brain is configured to perform a boundary scan test using the DIOS module carrier to access the UUT.

In some implementations, the functional platform brain is configured to perform a radiofrequency (RF) test on the UUT.

In some implementations, the FCT includes applying a stimulus to the UUT, measuring a response from the UUT, and analyzing the response from the UUT.

In some implementations, the functional platform brain is further configured to perform in-system programming, on-board programming, an engineering verification test, or a production verification test. Alternatively or additionally, the functional platform brain is configured to, using a machine learning algorithm, troubleshoot FCT diagnostic issues.

It should be understood that the above-described subject matter may also be implemented as a computer-controlled apparatus, a computer process, a computing system, or an article of manufacture, such as a computer-readable storage medium.

Other systems, methods, features and/or advantages will be or may become apparent to one with skill in the art upon examination of the following drawings and detailed description. It is intended that all such additional systems, methods, features and/or advantages be included within this description and be protected by the accompanying claims.

### BRIEF DESCRIPTION OF THE DRAWINGS

The components in the drawings are not necessarily to scale relative to each other. Like reference numerals designate corresponding parts throughout the several views.

FIG. 1 is a system block diagram of an integrated test system according to an implementation of the present disclosure.

FIG. 2 illustrates an example computing device.

FIG. 3 illustrates a test system according to an implementation of the present disclosure.

FIG. 4 illustrates the structure and format of commands that can be part of a test sequence protocol, according to a non-limiting example implementation of the present disclosure.

### DETAILED DESCRIPTION

Unless defined otherwise, all technical and scientific terms used herein have the same meaning as commonly understood by one of ordinary skill in the art. Methods and materials similar or equivalent to those described herein can be used in the practice or testing of the present disclosure. As used in the specification, and in the appended claims, the singular forms “a,” “an,” “the” include plural referents unless the context clearly dictates otherwise. The term “comprising” and variations thereof as used herein is used synonymously with the term “including” and variations thereof and are open, non-limiting terms. The terms “optional” or “optionally” used herein mean that the subsequently described feature, event or circumstance may or may not occur, and that the description includes instances where said feature, event or circumstance occurs and instances where it does not. Ranges may be expressed herein as from “about” one particular value, and/or to “about” another particular value. When such a range is expressed, an aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint. While implementations will be described for testing printed circuit boards, it will become evident to those skilled in the art that the implementations are not limited thereto, but are applicable for performing other automated tests on other electronics.

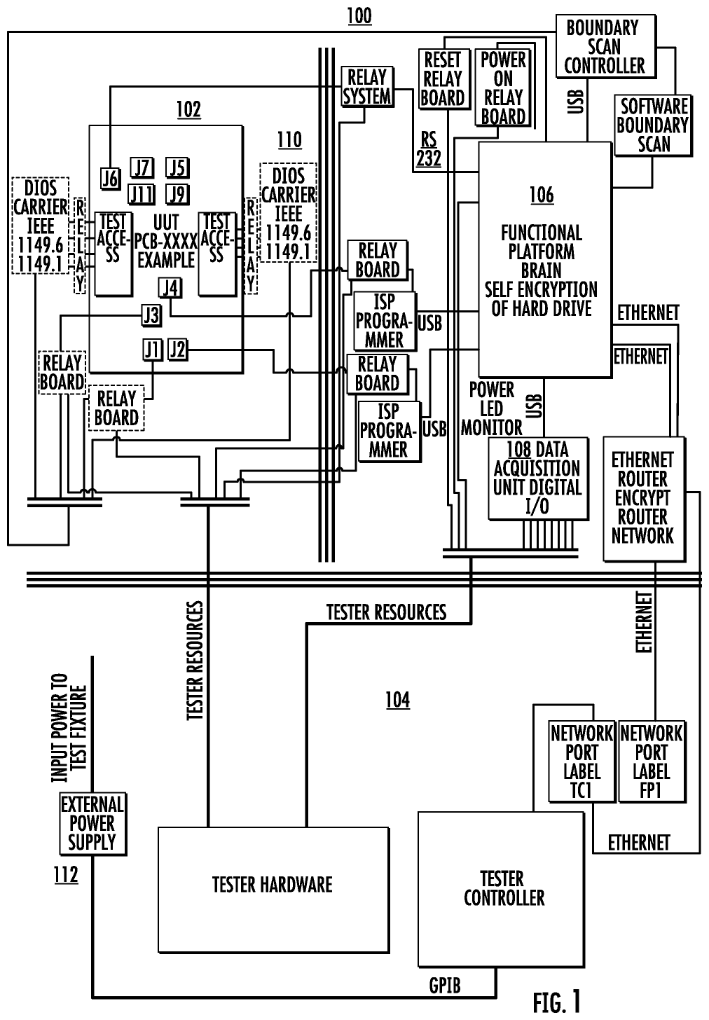

With reference to FIG. 1, a system block diagram representing an implementation of the present disclosure is illustrated. The integrated test system 100 can include a unit under test (UUT) 102, and a test development system 104. As shown in FIG. 1, the test development system 104 can include tester hardware, a tester controller, a power supply, and communication interfaces. It should be understood that the test development system 104 more or less components than shown in FIG. 1. As described below, test development systems are known in the art. The unit under test 102 can be operably coupled to the test development system 104. A unit under test is the object (e.g., a PCB) being tested and is sometimes referred to as a device under test (DUT) or equipment under test (EUT). The UUT 102 and the test development system 104 discussed above can be coupled through one or more communication links. This disclosure contemplates the communication links are any suitable communication link. For example, a communication link may be implemented by any medium that facilitates data exchange between the UUT 102 and the test development system 104 including, but not limited to, wired, wireless and optical links. The test development system 104 can be configured to perform in-circuit testing (ICT) on the UUT 102. In-circuit testing is a probe test of a UUT such as a PCB to check for issues during fabrication such as shorts, opens, resistance, capacitance, or other quality of the UUT. ICT includes, but is not limited to, one or more of a capacitor discharge test, a contact test, a short test, an analog component test, a digital component test, an open pin test, a capacitor orientation test, a UUT power up test, a boundary scan test, or a memory test. In-circuit testing is known in the art and therefore not described in further detail herein. Test development systems 104 are manufactured by companies including, but not limited to, Keysight Technologies of Santa Rosa, Calif. and Teradyne Inc. of Boston, Mass.

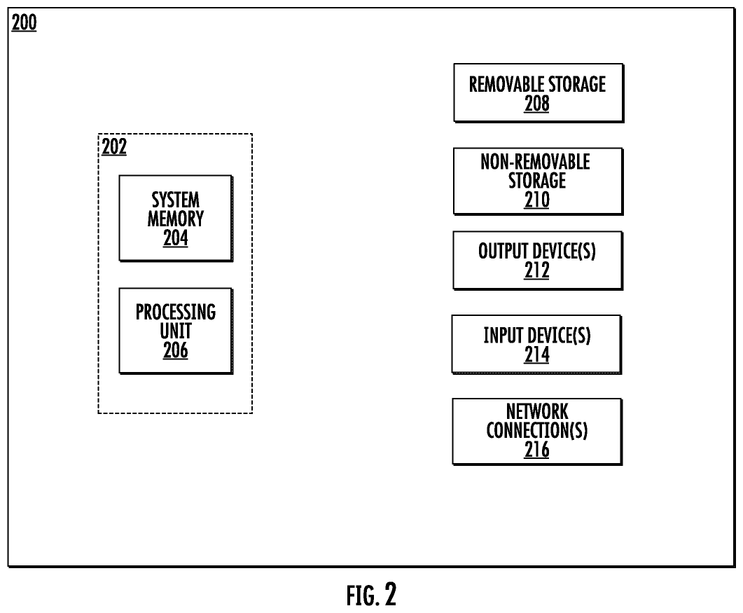

A functional platform brain 106 can be operably coupled to the test development system 104 and the UUT 102, for example, using one or more communication links. The functional platform brain 106 can be configured to perform functional testing (FCT) on the UUT 102 using a test sequence protocol. Functional testing is a quality assurance process that involves applying a stimulus to the UUT 102, measuring a response signal from the UUT 102, and analyzing the response signal from the UUT 102 to ensure that the UUT 102 has been fabricated to specification. The functional platform brain 106 can be a computing device, or combination of computing devices. For example, the functional platform brain 106 can be implemented by the computing device 200 shown in FIG. 2. Conversely, one or more computing devices 200 shown in FIG. 2 can be combined to implement the functional platform brain 106. In some implementations of the present disclosure, an expandable PCB can be used to implement part or all of the functional platform brain 106. As a non-limiting example, in some implementations a motherboard (e.g. a personal computer motherboard) can be used to implement the functional platform brain 106.

In some implementations described herein, the functional platform brain 106 can be implemented on an ITX, STX, ATX, UTX, or x86 type motherboard configured to communicate to the test development system 104 using the Test Sequence Protocol through a Data Acquisition System/Unit (e.g., the data acquisition unit 108) to the test development system's testhead. In some implementations described herein, the functional platform brain 106 can support any x86 software or application in addition to any serial or parallel or any x86 supported communication protocol. The functional platform brain 106 interfaces to the UUT 102 (e.g. a PCBA) through connectors or test access points.

Implementations of the present disclosure include an Intelligent Integrated Test System 100. The intelligent integrated test system 100 can be an In-circuit/Functional Test Fixture hybrid that integrates a test development system 102 and a functional platform brain 106, creating an intelligent test fixture that is capable of communicating to the test development system 104 and can allow the test development system 104 to communicate to the functional platform brain 106.

The Intelligent Integrated Test System 100 can optimize each of several test methodologies (both ICT and FCT) to integrate into each of the test development system 104 and functional platform brain 106 respective test environments without a reduction in the capabilities of each test methodology.

The present disclosure contemplates that any standalone Engineering Verification Testing, Design Verification Testing or Production Verification Testing/Functional Testing/Processor Emulation/Simulation/Self Diagnostics/Instrumentation/PXI/RF or any x86 supported test can be integrated into the Intelligent Integrated Test System 100, without compromising how the test methodology is executed, developed, or originally designed for testing.

Furthermore, in some implementations, the Intelligent Integrated Test System 100 can optimize each test methodology (i.e., ICT and FCT), in addition to allowing each test methodology to complement the other test methodologies in areas where reduce test coverage can be increased. As a non-limiting example, the boundary scan test has three JTAG ports which one port is disabled due to a pin that needs to be driven HIGH, in addition to a CONFIG pin on an ASIC that needs to be driven LOW to allow use of the BSDL chain to increase the Boundary Scan test coverage from 76% to 96%. The In-circuit test can control these pins thus allowing for an increase in test coverage.

Implementations described herein can allow for increased test coverage, a higher level of test methodology integration, removal of manufacturing process steps related to the need of multiple test processes to increase test coverage of the UUT 102. Additionally, some implementations of the present disclosure can operate with any test and/or measurement tool. As a non-limiting example, an OEM (original equipment manufacturer) can use implementations of the present disclosure with a component manufacturer's development tools for programming, test development, measurement, and test and integrate these tools into the Intelligent Integrated Test System 100 as is without limiting the functions of these tests or tools.

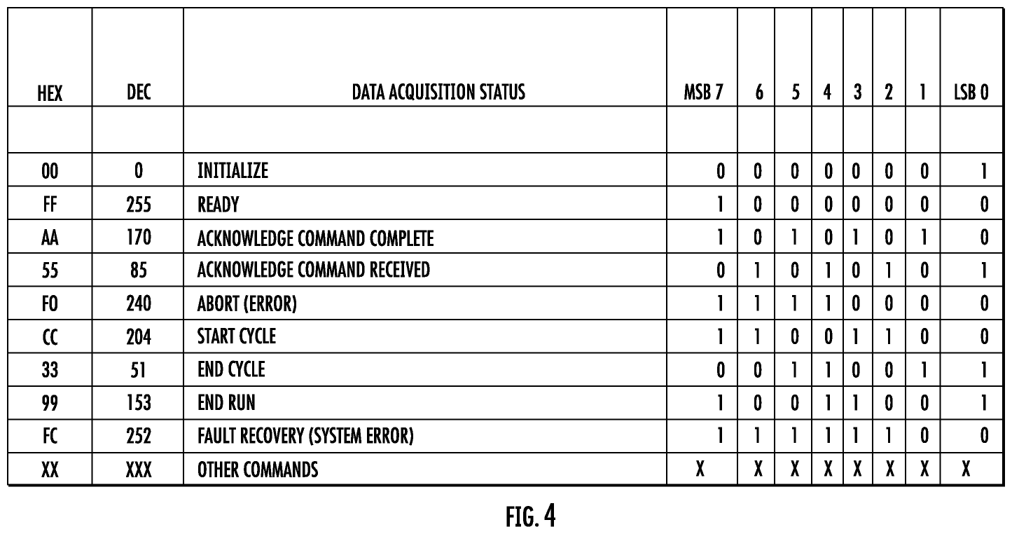

The functional platform brain 106 can include intelligent integrated test system software (IITSS). IITSS can be software executed on the functional platform brain 106 that translates the communication protocol that is the Test Sequence Protocol (e.g., the non-limiting example protocol illustrated in FIG. 4) to allow communication between the test development system 104 and the functional platform brain 106 to facilitate execution of a test program. Optionally, IITSS is embedded software (e.g., stored in memory) of the functional platform brain 106. The IITSS can diagnose issues discovered with an Intelligent Integrated Test System 100 and selfheal software issues and route a solution to that resolves hardware issues. The IITSS can implement artificial intelligence (e.g., one or more artificial neural networks) that can be configured to resolve issues with the IITSS and the Intelligent Integrated Test System 100. This software can allow the integration of many or all test methodologies in the test program. Non-limiting examples of test methodologies that can be combined in a test program include Boundary Scan/JTAG Testing, In-system Programming/ISP, On-Board Programming, and Engineering Verification Testing, Design Verification Testing, Production Verification Testing, Functional Testing, RF Testing, and/or any other type of testing configured to test the Unit Under Test 102.

Implementations of the present disclosure include a test sequence protocol. The test sequence protocol is the communication protocol that allows execution of commands, handshaking, and acknowledgement of commands including other commands as needed the test program to operate.

As a non-limiting example, a Hexadecimal, Decimal, or Multi-bit form from Most Significant Bit (MSB) to Least Significant Bit (LSB) format can be used as part of the test sequence protocol to facilitate communication between the functional platform brain 106 and the test development system 104.

A non-limiting example of how these commands can be structured and formatted in one implementation is shown in FIG. 4. It should be understood that the commands illustrated in FIG. 4 are provided only as examples. This disclosure contemplates that the test sequence protocol can include more, less, and/or different commands. The test sequence protocol defines a format for exchanging messages between the test development system 104 and the functional platform brain 106.

To show the executed command's Test Results, diagnostics, or to execute administrative commands, this information, executed commands, and received commands are communicated across a RJ45 Ethernet/Network port into a broadband router out to a Network Interface Card inside the Test Controller of the Teradyne/Genrad or Keysight Technologies/Agilent Technologies Board Test Development System. This information is placed in a shared folder between the functional platform brain and the Teradyne/Genrad or Keysite Technologies/Agilent Technologies Board Test Development System. This provides bidirectional information to and from the functional platform brain and the Teradyne/Genrad or Keysight Technologies/Agilent Technologies Board Test Development System.

Implementations of the present disclosure can include the ability to execute program code as part of the functional platform brain 106. Additionally, implementations described herein can be user programmable, for example a user can create or upload code to the to test development system 104 and/or functional platform brain 106 in order to automate testing operations. Non-limiting examples of programming languages that can be used include VB.NET, VB 6, C, C++, C#, DOS, PYTHON, MATLAB and any x86 supported programming language.

Similarly, implementations of the present disclosure can include one or more communication protocols for operably connecting the test development system 104, functional platform brain 106, and other components. Non-limiting examples of communications protocols that can be used include the serial communication protocol, USB 2.0, USB 3.0, TCP IP, IPV6, RS232, SPI, I2C, IEEE 1394 UART, CAN, RS422, RS485, MICROWIRE, SERIAL ATA and any other x86 supported serial communication protocol, as well as the parallel communication protocol, GPIB (IEEE-488), IEEE 1284, RAID, SSD, PARALLEL ATA, EIDE ISA, ATA, SCSI, PCI, Paex and Front side bus and any other x86 supported parallel communication protocol.

It should be understood that implementations described herein can be used in combination with, or as part of, other testing equipment, and non-limiting examples of such equipment include GPIB (IEEE-488) and RS232.

Implementations described herein can implement multiple types of test sequence protocol. The test sequence protocol can be any protocol that can be configured to facilitate communication between the test development system 104 and the functional platform brain 106. A non-limiting example of a test sequence protocol is a handshake protocol. The test sequence protocol (including, as a non-limiting example, a handshake protocol) can define a format for exchanging messages between the test development system 104 and the functional platform brain 106. The messages exchanged between the test development system 104 and the functional platform brain 106 can include, as non-limiting examples, messages including or related to test instructions, test information, and test results.

The present disclosure contemplates that any suitable format can be used for exchanging messages between the test development system 104 and the functional platform brain 106. As non-limiting examples, in implementations of the present disclosure, the message format can be any of a hexadecimal, decimal, or multi-bit format.

In some implementations of the present disclosure, test sequence protocol can be configured to facilitate communication between the functional platform brain 106 and an application running on the test development system 104. The test development system 104 can also be connected to one or more test points of the UUT 102. Similarly, the functional platform brain 106 can be connected to one or more test access ports on the UUT 102. It is also contemplated that implementations described herein can connect to any combination of test access ports and test points located on the UUT 102. Non-limiting examples of types of test access ports that can be used include JTAG, USB, RS232, or any other interface with which functional platform brain 106 (e.g. a motherboard) can send/receive data to the UUT 102.

Furthermore, some implementations of the present disclosure include a data acquisition unit (DAQ). The DAQ 108 can be used to allow communication between the test development system and functional platform brain. In some implementations, the DAQ 108 couples a multibit interface of the test development system 104 with a serial port of the functional platform brain 106.

Some implementations of the present disclosure can include a digital input/output scan (DIOS) module carrier. The DIOS module carrier 110 can couple the functional platform brain 106 to a plurality of test points of the UUT 102. In some implementations, the functional platform brain 106 can perform a boundary scan test using the DIOS module carrier 110 to access the UUT 102. For example, Boundary Scan software and controllers can be installed on the Functional Platform Brain 106.

In some implementations described herein, two or more DIOS module carriers 110 can be connected to test probes through relay subsystems that are subsequently connected to test points on the UUT 102. In this configuration, the DIOS Carriers 110 can perform as IEEE 1149.1 compliant devices that are functional extensions of the PCBA. This allows for testing components that have no test access; in addition, a user is able to test a UUT that has no boundary scan capable component on the UUT with a Boundary Scan test.

Other tests are contemplated by the present disclosure. In some implementations, the functional platform brain 106 can be configured to perform a radiofrequency (RF) test on the UUT 102. For example, in some implementations, the test development system 104 is not configured to generate or provide the signals or measurements for conventional RF testing. In some implementations of the present disclosure, the Intelligent Integrated Test System 100 can allow for RF Testing with the functional platform brain 106 using the Intelligent Integrated Test System Software and a Test Sequence Protocol. In some implementations described herein, the Applications and/or Programs for RF Tests can be executed using the Intelligent Integrated Test System Software that is embedded software on the functional platform brain 106. The Intelligent Integrated Test System Software using the Test Sequence Protocol can control some or all of the Applications and/or Programs needed to execute RF Tests. In some implementations, the Intelligent Integrated Test System Software can also control some or all of the communication from the test development system 104 that can assist in the testing of the UUT 102.

External Instrumentation can be controlled by the GPIB (IEEE 488) attached to the test development system 104 or a GPIB/RS232/USB/Ethernet or another suitable Instrumentation Controller Device that would be controlled by the functional platform brain 106. Outputs and/or inputs for measurements and signals that are received and sent from the external instrumentation can interface to the Test Fixture through a diverse number of access points. Non-limiting examples of access points that can be used to access the outputs and/or inputs from the external instrumentation include switches, relays, isolators, and direct interfaces. Any suitable connection can be used to the UUT 102. To resolve insertion loss, the signaling cables can have the measurement of loss determined for the signaling cables with a Network Analyzer and these losses can be subtracted from the actual measurements made with the external instrumentation to measure the signals on the UUT 102. In some implementations of the present disclosure, the calibration routines can have insertion losses for the UUT 102 to less than 2 dB.

Some implementations can perform ICT. Non-limiting examples of ICT that can be performed include capacitor discharge tests, contact tests, short tests, analog component tests, digital component tests, open pin tests, capacitor orientation tests, UUT power up tests, boundary scan tests, and/or memory test. It should be understood that implementations described herein can perform these and other tests in different combinations.

In some implementations, the FCT can include applying a stimulus to the UUT 102, measuring a response from the UUT 102, and analyzing the response from the UUT 102. The functional platform brain 106 can also be configured to perform in-system programming, on-board programming, engineering verification tests, and/or production verification tests.

It is also contemplated by the present disclosure that machine learning algorithms can be employed by the functional platform brain 106. Non-limiting examples of machine learning algorithms include artificial neural networks, which can include a combination of algorithms, interconnected nodes, and weights. The present disclosure contemplates that the functional platform brain 106 can implement a machine learning algorithm that is configured to identify and/or troubleshoot test issues. For example, the functional platform brain 106 can be configured to, using a machine learning algorithm, troubleshoot FCT diagnostic issues, or any other types of diagnostic issues. It should be understood that these are only non-limiting examples of machine learning techniques and applications, and that other uses of machine learning by the functional platform brain 106 are contemplated by the present disclosure.

An external power supply or internal power supply 112 can be installed in the Intelligent Integrated Test System 100. The power supply 112 can be configured to systematically power up and shut down the fixture electronics in the Intelligent Integrated Test System 100.

The power supply 112 can provide power to some or all of the electronics in the Intelligent Integrated Test System 100.

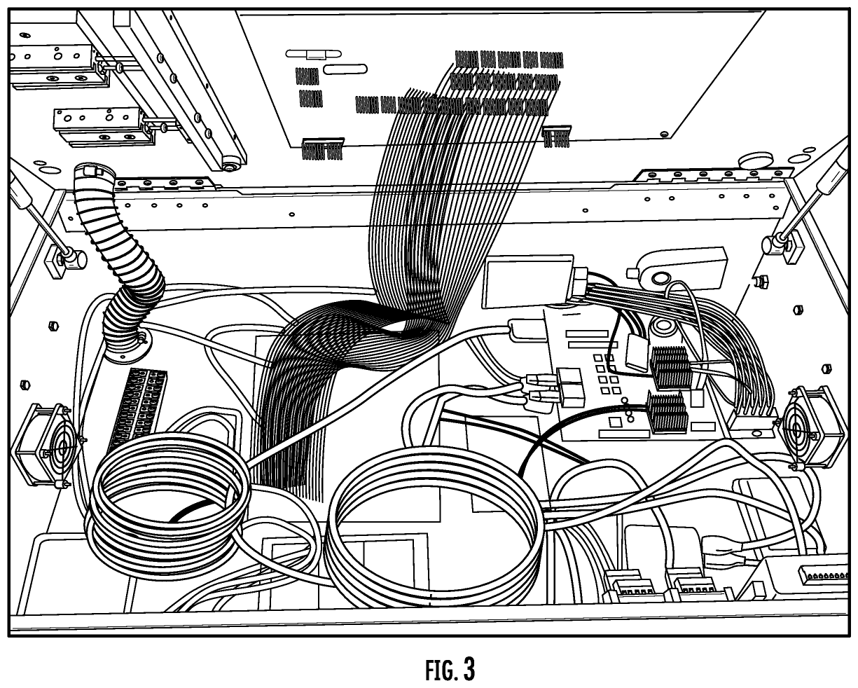

In some implementations of the present disclosure, a functional platform brain 106 is part of an intelligent test fixture. The intelligent test fixture can include the functional platform brain 106, and the functional platform brain 106 can be configured to perform functional testing on a UUT 102. The functional platform brain 106 can be configured to use a test sequence protocol, where the test sequence protocol can be a test sequence protocol configured to facilitate communication between a test development system 104 and the functional platform brain 106. FIG. 3 illustrates an intelligent test fixture, according to one implementation of the present disclosure.

It should be appreciated that the logical operations described herein with respect to the various figures may be implemented (1) as a sequence of computer implemented acts or program modules (i.e., software) running on a computing device (e.g., the computing device described in FIG. 2), (2) as interconnected machine logic circuits or circuit modules (i.e., hardware) within the computing device and/or (3) a combination of software and hardware of the computing device. Thus, the logical operations discussed herein are not limited to any specific combination of hardware and software. The implementation is a matter of choice dependent on the performance and other requirements of the computing device. Accordingly, the logical operations described herein are referred to variously as operations, structural devices, acts, or modules. These operations, structural devices, acts and modules may be implemented in software, in firmware, in special purpose digital logic, and any combination thereof. It should also be appreciated that more or fewer operations may be performed than shown in the figures and described herein. These operations may also be performed in a different order than those described herein.

Referring to FIG. 2, an example computing device 200 upon which the methods described herein may be implemented is illustrated. It should be understood that the example computing device 200 is only one example of a suitable computing environment upon which the methods described herein may be implemented. Optionally, the computing device 200 can be a well-known computing system including, but not limited to, personal computers, servers, handheld or laptop devices, multiprocessor systems, microprocessor-based systems, network personal computers (PCs), minicomputers, mainframe computers, embedded systems, and/or distributed computing environments including a plurality of any of the above systems or devices. Distributed computing environments enable remote computing devices, which are connected to a communication network or other data transmission medium, to perform various tasks. In the distributed computing environment, the program modules, applications, and other data may be stored on local and/or remote computer storage media.

In its most basic configuration, computing device 200 typically includes at least one processing unit 206 and system memory 204. Depending on the exact configuration and type of computing device, system memory 204 may be volatile (such as random access memory (RAM)), non-volatile (such as read-only memory (ROM), flash memory, etc.), or some combination of the two. This most basic configuration is illustrated in FIG. 5 by dashed line 202. The processing unit 206 may be a standard programmable processor that performs arithmetic and logic operations necessary for operation of the computing device 200. The computing device 200 may also include a bus or other communication mechanism for communicating information among various components of the computing device 200.

Computing device 200 may have additional features/functionality. For example, computing device 200 may include additional storage such as removable storage 208 and non-removable storage 210 including, but not limited to, magnetic or optical disks or tapes. Computing device 200 may also contain network connection(s) 516 that allow the device to communicate with other devices. Computing device 200 may also have input device(s) 214 such as a keyboard, mouse, touch screen, etc. Output device(s) 212 such as a display, speakers, printer, etc. may also be included. The additional devices may be connected to the bus in order to facilitate communication of data among the components of the computing device 200. All these devices are well known in the art and need not be discussed at length here.

The processing unit 206 may be configured to execute program code encoded in tangible, computer-readable media. Tangible, computer-readable media refers to any media that is capable of providing data that causes the computing device 200 (i.e., a machine) to operate in a particular fashion. Various computer-readable media may be utilized to provide instructions to the processing unit 206 for execution. Example tangible, computer-readable media may include, but is not limited to, volatile media, non-volatile media, removable media and non-removable media implemented in any method or technology for storage of information such as computer readable instructions, data structures, program modules or other data. System memory 204, removable storage 208, and non-removable storage 210 are all examples of tangible, computer storage media. Example tangible, computer-readable recording media include, but are not limited to, an integrated circuit (e.g., field-programmable gate array or application-specific IC), a hard disk, an optical disk, a magneto-optical disk, a floppy disk, a magnetic tape, a holographic storage medium, a solid-state device, RAM, ROM, electrically erasable program read-only memory (EEPROM), flash memory or other memory technology, CD-ROM, digital versatile disks (DVD) or other optical storage, magnetic cassettes, magnetic tape, magnetic disk storage or other magnetic storage devices.

In an example implementation, the processing unit 206 may execute program code stored in the system memory 204. For example, the bus may carry data to the system memory 204, from which the processing unit 206 receives and executes instructions. The data received by the system memory 204 may optionally be stored on the removable storage 208 or the non-removable storage 210 before or after execution by the processing unit 206.

It should be understood that the various techniques described herein may be implemented in connection with hardware or software or, where appropriate, with a combination thereof. Thus, the methods and apparatuses of the presently disclosed subject matter, or certain aspects or portions thereof, may take the form of program code (i.e., instructions) embodied in tangible media, such as floppy diskettes, CD-ROMs, hard drives, or any other machine-readable storage medium wherein, when the program code is loaded into and executed by a machine, such as a computing device, the machine becomes an apparatus for practicing the presently disclosed subject matter. In the case of program code execution on programmable computers, the computing device generally includes a processor, a storage medium readable by the processor (including volatile and non-volatile memory and/or storage elements), at least one input device, and at least one output device. One or more programs may implement or utilize the processes described in connection with the presently disclosed subject matter, e.g., through the use of an application programming interface (API), reusable controls, or the like. Such programs may be implemented in a high level procedural or object-oriented programming language to communicate with a computer system. However, the program(s) can be implemented in assembly or machine language, if desired. In any case, the language may be a compiled or interpreted language and it may be combined with hardware implementations.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

1. An integrated test system, comprising:
a unit under test (UUT); and
a test development system operably coupled to the UUT, the test development system being configured to perform in-circuit testing (ICT) on the UUT; and
a functional platform brain operably coupled to the test development system and the UUT, the functional platform brain being configured to perform functional testing (FCT) on the UUT using a test sequence protocol, wherein the test sequence protocol is configured to facilitate communication between the test development system and the functional platform brain.

2. The system of claim 1, wherein the test sequence protocol comprises a handshake protocol.

3. The system of claim 1, wherein the test sequence protocol defines a format for exchanging messages between the test development system and the functional platform brain.

4. The system of claim 3, wherein the format for exchanging messages is at least one of a hexadecimal, decimal, or multi-bit format.

5. The system of claim 1, wherein the test sequence protocol is further configured to facilitate communication between the functional platform brain and an application running on the test development system.

6. The system of claim 1, wherein the test development system is operably coupled to a plurality of test points of the UUT.

7. The system of claim 1, wherein the functional platform brain is operably coupled to a test access port and a plurality of test points of the UUT.

8. The system of claim 1, further comprising a data acquisition unit (DAQ), wherein the DAQ operably couples a multibit interface of the test development system to a serial port of the functional platform brain.

9. The system of claim 1, further comprising a digital input/output scan (DIOS) module carrier, wherein the DIOS module carrier operably couples the functional platform brain to a plurality of test points of the UUT.

10. The system of claim 9, wherein the functional platform brain is configured to perform a boundary scan test using the DIOS module carrier to access the UUT.

11. The system of claim 1, wherein the functional platform brain is configured to perform a radiofrequency (RF) test on the UUT.

12. The system of claim 1, wherein the ICT comprises one or more of a capacitor discharge test, a contact test, a short test, an analog component test, a digital component test, an open pin test, a capacitor orientation test, a UUT power up test, a boundary scan test, or a memory test.

13. The system of claim 1, wherein the FCT comprises applying a stimulus to the UUT, measuring a response from the UUT, and analyzing the response from the UUT.

14. The system of claim 1, wherein the functional platform brain is further configured to perform in-system programming, on-board programming, an engineering verification test, or a production verification test.

15. The system of claim 1, wherein the functional platform brain is configured to, using a machine learning algorithm, troubleshoot FCT diagnostic issues.

16. An intelligent test fixture, comprising:
a functional platform brain that is configured to perform functional testing (FCT) on a unit under test (UUT), wherein the functional platform brain is configured to use a test sequence protocol, the test sequence protocol being configured to facilitate communication between a test development system and the functional platform brain.

17. The test fixture of claim 16, wherein the test sequence protocol comprises a handshake protocol.

18. The test fixture of claim 16, wherein the test sequence protocol defines a format for exchanging messages between the test development system and the functional platform brain.

19. The test fixture of claim 18, wherein the format for exchanging messages is at least one of a hexadecimal, decimal, or multi-bit format.

20. The test fixture of claim 16, wherein the test sequence protocol is further configured to facilitate communication between the functional platform brain and an application running on the test development system.

21. The test fixture of claim 16, wherein the functional platform brain is operably coupled to a test access port and a plurality of test points of the UUT.

22. The test fixture of claim 16, further comprising a digital input/output scan (DIOS) module carrier, wherein the DIOS module carrier operably couples the functional platform brain to a plurality of test points of the UUT.

23. The test fixture of claim 22, wherein the functional platform brain is configured to perform a boundary scan test using the DIOS module carrier to access the UUT.

24. The test fixture of claim 16, wherein the functional platform brain is configured to perform a radiofrequency (RF) test on the UUT.

25. The test fixture of claim 16, the FCT comprises applying a stimulus to the UUT, measuring a response from the UUT, and analyzing the response from the UUT.

26. The test fixture of claim 16, wherein the functional platform brain is further configured to perform in-system programming, on-board programming, an engineering verification test, or a production verification test.

27. The test fixture of claim 16, wherein the functional platform brain is configured to, using a machine learning algorithm, troubleshoot FCT diagnostic issues.
